(19) United States
(12) Patent Application Publication
(10) Pub. No.: US 2019/0018070 A1
(43) Pub. Date: Jan. 17, 2019

(54) SECONDARY BATTERY DEGRADATION DETERMINATION DEVICE

(71) Applicant: NTN CORPORATION, Osaka (JP)

(72) Inventor: Hiroyuki YAMADA, Iwata (JP)

(73) Assignee: NTN CORPORATION, Osaka (JP)

(21) Appl. No.: 16/134,267

(22) Filed: Sep. 18, 2018

Related U.S. Application Data
(63) Continuation of application No. PCT/JP2017/010541, filed on Mar. 15, 2017.

(30) Foreign Application Priority Data
Mar. 18, 2016 (JP) 2016-054774

(51) Int. Cl. G01R 31/36; H02J 7/00; H01M 10/48; H01M 10/44

(52) U.S. Cl. CPC G01R 31/3679; G01R 31/3662; G01R 31/3658; H01M 2220/10; H01M 10/482; H01M 10/441; H02J 7/0021

(57) ABSTRACT

The secondary battery degradation determination device includes: a plurality of voltage sensors connected to the respective batteries; a discharging circuit connected in parallel to each battery group; and a discharge controller. The discharge controller drives a switching element so as to open and close such that current flowing in the discharging circuit has a pulse shape or the like. Each voltage sensor measures a voltage value of the AC component. On the basis of the measurement value, the internal resistance calculation section calculates an internal resistance, and a determination section determines degradation of the battery on the basis of the internal resistance.

### CROSS REFERENCE TO THE RELATED APPLICATION

This application is a continuation application, under 35 U.S.C. § 111(a), of international application No. PCT/JP2017/010541, filed Mar. 15, 2017, which is based on and claims Convention priority to Japanese patent application No. 2016-054774, filed Mar. 18, 2016, the entire disclosure of which is herein incorporated by reference as a part of this application.

### BACKGROUND OF THE INVENTION

### Field of the Invention

The present invention relates to a degradation determination device which determines degradation of a secondary battery that is used in an emergency power supply or the like in data centers, mobile phone base stations, or other various types of power supply devices for which stable electric power supply is required.

### Description of Related Art

In data centers, mobile phone base stations, or the like, stable supply of electric power is important. Although a commercial AC power supply is used during steady operation, such a data center, a mobile phone base station, or the like is provided with an emergency power supply in which a secondary battery is used, as an uninterruptible power supply device, for a case where the commercial AC power supply stops. Charging methods for the emergency power supply includes: a trickle charging type in which charging is carried out with a minute current by use of a charging circuit during steady operation; and a float charging type in which a load and a secondary battery are connected in parallel to a rectifier, and charging is carried out while the load is being operated with a constant current being applied. In general, the trickle charging type is more often employed in the emergency power supply.

The emergency power supply is required to have voltage and current that allow driving of a load that is driven by the commercial power supply. Since a single secondary battery (also referred to as battery) has low voltage and a small capacity, the emergency power supply is configured such that a plurality of battery groups are connected in parallel, each battery group including a plurality of batteries that are connected in series. The individual battery is a lead storage battery, a lithium ion battery, or the like.

In such an emergency power supply, the voltages of the batteries decrease due to degradation. Therefore, in order to ensure reliability, it is desired that degradation determination of each battery is performed and any battery that has been degraded is replaced. However, there has been no proposal of a device that can perform accurate degradation determination on a large number of batteries in a large-scale emergency power supply such as in a data center, a mobile phone base station, or the like.

Examples of proposals regarding conventional battery degradation determination include: a proposal of an on-vehicle battery checker that performs measurement on the entire battery (for example, Patent Document 1); a proposal in which a pulse-shaped voltage is applied to a battery and the internal impedance of the entire battery is calculated from an input voltage and a response voltage (for example, Patent Document 2); and a proposal of a method in which internal resistance of each of individual cells connected in series in a battery is measured, whereby degradation is determined (for example, Patent Document 3). For measurement of the internal resistance of each individual cell, an AC 4-terminal-method is used. As a handy checker that measures a very small resistance value such as internal resistance of a battery, an AC 4-terminal-method battery tester has been commercialized (for example, Non-Patent Document 1).

In Patent Documents 1 and 2 mentioned above, wireless data transmission is also proposed, and in addition, reduction of handling of cables and manual work, and data management by computers are also proposed.

### RELATED DOCUMENT

### Patent Document

[Patent Document 1] JP Laid-open Patent Publication No. H10-170615
[Patent Document 2] JP Laid-open Patent Publication No. 2005-100969
[Patent Document 3] JP Laid-open Patent Publication No. 2010-164441

### Non-Patent Document

[Non-Patent Document 1] AC 4-terminal-method battery tester, internal resistance measuring instrument IW7807-BP (Rev. 1.7.1, Feb. 16, 2015, Tokyo Devices) (https://tokyodevices.jp/system/attachments/files/000/000/298/original/IW7807-BP-F_MANUAL.pdf)

The conventional handy checker (Non-Patent Document 1) requires too many measurement positions, and thus, is not practical for an emergency power supply in which tens and hundreds of batteries are connected. Each of the technologies according to Patent Documents 1 and 2 is for performing measurement of the entirety of a power supply that include batteries, and is not for performing measurement of individual batteries, i.e., individual cells. Therefore, the accuracy of degradation determination is low, and individual batteries that have been degraded cannot be identified.

In terms of measuring the internal resistance of each of individual cells connected in series, the technology according to Patent Document 3 leads to improvement of accuracy in degradation determination, and to a technology that identifies individual batteries that have been degraded. However, since the AC 4-terminal-method is used for measurement of the internal resistance of each individual cell, the configuration is complicated and it is difficult to commercialize the technology for a large-scale emergency power supply that has several tens to several hundreds of cells.

A relatively simple device that can accurately determine degradation of a battery employs a method in which current having an AC component such as ripple current or pulse current is applied to the battery, and the internal resistance of the battery is measured on the basis of the AC component of voltage between terminals of the battery, thereby determining degradation. However, there has been no proposal of a technology that can generate ripple current, that is simple in configuration, and that can be inexpensively produced.

### SUMMARY OF THE INVENTION

An object of the present invention is to provide a secondary battery degradation determination device that is simple, that can be inexpensively produced, and that can accurately determine degradation of each of batteries in a power supply in which a plurality of battery groups are connected in parallel, each battery group including a plurality of batteries that are connected in series, each battery being a secondary battery, wherein, in particular, a generation means for measurement current containing an AC component has a simple and compact configuration.

Hereinafter, in order to facilitate understanding of the present invention, the present invention will be described with reference to the reference numerals used in embodiments, for the sake of convenience.

A secondary battery degradation determination device of the present invention is for batteries in a power supply 1 in which a plurality of battery groups 3 are connected in parallel or a single battery group 3 is provided, each battery group 3 being connected to a load and including a plurality of batteries 2 that are connected in series, each battery 2 being a secondary battery, the secondary battery degradation determination device being configured to determine degradation of each of the batteries 2 and including:

a plurality of voltage sensors 7, each individually connected to a corresponding battery 2, and each configured to measure voltage of an AC component of voltage that has been applied to the battery;

a discharging circuit 9 connected in parallel to the battery group 3 and implemented as a series circuit of a current limiting resistor 26 and a switching element 27;

a discharge controller 11e configured to drive the switching element 27 so as to open and close such that current flowing in the discharging circuit 9 becomes current having a pulse shape or a sine wave shape;

an internal resistance calculation section 13a configured to calculate an internal resistance of each battery 2 provided with the corresponding voltage sensor 7, by use of a measurement value measured by the voltage sensor 7; and a determination section 13b configured to determine degradation of the battery 2 by use of the internal resistance calculated by the internal resistance calculation section 13a.

The power supply 1 is an emergency power supply provided to a data center or a mobile phone base station, for example.

It should be noted that the AC component herein is a component the magnitude of voltage of which repeatedly changes. The direction of the voltage thereof may be always constant or the AC component may be ripple current or pulse current, for example. The “battery” may be a plurality of cells connected in series, or may be a single cell.

According to this configuration, an AC component is provided to each battery 2 and voltage of the AC component is measured by the corresponding voltage sensor 7. The internal resistance of the battery 2 is calculated by use of this measurement value, and degradation of the battery 2 is determined on the basis of the internal resistance. Thus, degradation can be accurately determined. The internal resistance of the battery 2 has a close relationship with the capacity of the battery 2, that is, the degree of degradation thereof, and thus, if the internal resistance is known, degradation of the battery 2 can be accurately determined. In addition, degradation is determined not for the entirety of the power supply 1 subjected to degradation determination but for each of the individual batteries 2. In this configuration, measurement current containing the AC component is generated, and the internal resistance of the battery 2 is measured to determine degradation, and thus, the measurement can be performed in a relatively simple configuration.

Although a means that generates the AC component for the battery 2 is necessary, measurement current is generated through discharge. That is, the switching element 27 is driven to open and close by the discharge controller 11e such that current flowing in the discharging circuit 9 becomes current having a pulse shape or a sine wave shape. Thus, no commercial power supply or no power supply device that produces measurement current from the commercial power supply is necessary, and the means that generates measurement current can be realized by a simple and compact configuration implemented as the discharging circuit 9 formed by the current limiting resistor 26 and the switching element 27. In this manner, degradation of each battery 2 can be accurately determined, and each of the means that performs from detection of voltage or the like to determination and the means that generates measurement current is simple. Thus, as a whole, a secondary battery degradation determination device that is simple and that can be inexpensively produced is realized.

In the present invention, a current sensor 8 may be connected to each battery group 3, and the controller 11 may include: the internal resistance calculation section 13a which calculates the internal resistance of each battery 2 on the basis of the measurement value measured by a corresponding voltage sensor 7 and a measurement value measured by the current sensor 8 of a corresponding battery group 3 provided with the voltage sensor 7; and the determination section 13b which determines degradation of each battery 2 on the basis of a calculation result obtained by the internal resistance calculation section 13a. Even in a case where only voltage is measured, the internal resistance can be calculated with, for example, an assumption that current has a constant value. However, if the current actually flowing in the battery 2 is measured and both the voltage and the current are obtained, the internal resistance can be more accurately calculated. Since the current flowing in the batteries arranged in series is the same, it is sufficient that one current sensor 8 is provided for each battery group 3. Alternatively, a single current sensor 8 may be provided so as to be interposed between the parallel circuit of the battery groups 3 and the charging circuit 6, for example.

In the present invention, each voltage sensor 7 may include a conversion section 7bc configured to convert a measured voltage value into an effective value or an average value, and the internal resistance calculation section 13a may measure or calculate the internal resistance of the battery 2 on the basis of the effective value or the average value. Since the measurement value measured by each voltage sensor 7 is converted into an effective value or an average value to be transmitted as described above, when compared with a case where a signal having a voltage waveform is sent, the transmission data amount is significantly reduced. Calculation of the internal resistance of the battery 2 can be accurately performed by use of the effective value or the average value.

In the present invention, a sensor-specific wireless communicator 10 may be provided to each voltage sensor 7, the sensor-specific wireless communicator 10 configured to wirelessly transmit the measurement value measured by the corresponding voltage sensor. In a configuration in which data is received and transmitted through wireless communication, even if the emergency power supply 1 includes several tens to several hundreds of batteries 2, there is no need to take into consideration the electric reference potential (ground level) [volt] for each battery 2. Thus, neither differential operation nor an isolation transformer is required. In addition, since the measurement value measured by each of the plurality of voltage sensors 7 is wirelessly transmitted, no complicated wiring is necessary. Accordingly, a simple and inexpensive configuration can be realized.

The secondary battery degradation determination device of the present invention may be configured such that: a plurality of the battery groups 3 are connected in series to form a series connection body 3A; a plurality of the series connection bodies 3A are connected in parallel, and among the plurality of the series connection bodies 3A, portions “a” between individual battery groups 3 that correspond to each other are mutually connected; and among the plurality of the series connection bodies 3A, battery groups 3 that are connected in parallel to each other form a parallel connection body 3B, and the discharging circuit 9 is provided for each parallel connection body 3B.

In other words, in this configuration, if the series connection body 3A in the power supply 1 is considered as one battery group 3, this battery group 3 is divided into a plurality of battery group divided bodies 3a that are arranged in the series direction, the battery group divided bodies 3a are connected in parallel to the battery group divided bodies 3a of another battery group, and the discharging circuit 9 is provided in parallel to each parallel connection body 3B of the battery group divided bodies 3a. However, in each battery group divided body 3a, a plurality of batteries 2 are connected in series.

In a case where the power supply 1 is an emergency power supply or the like in a data center, voltage of the series connection bodies of the batteries in the entirety of the power supply 1 is high voltage that exceeds 300 V, for example. Therefore, if the discharging circuit 9 is provided for the entirety of the power supply 1, the switching element 27, which is a power element for applying measurement current, needs to have high withstand voltage. However, by employing a configuration in which the series connection body of the batteries 2 is divided into a plurality of parts in the series direction as described above, it is possible to use an element that has low withstand voltage, as the switching element 27 which is the power element for measurement current application in the discharging circuit 9.

Any combination of at least two constructions, disclosed in the appended claims and/or the specification and/or the accompanying drawings should be construed as included within the scope of the present invention. In particular, any combination of two or more of the appended claims should be equally construed as included within the scope of the present invention.

### BRIEF DESCRIPTION OF THE DRAWINGS

In any event, the present invention will become more clearly understood from the following description of preferred embodiments thereof, when taken in conjunction with the accompanying drawings. However, the embodiments and the drawings are given only for the purpose of illustration and explanation, and are not to be taken as limiting the scope of the present invention in any way whatsoever, which scope is to be determined by the appended claims. In the accompanying drawings, like reference numerals are used to denote like parts throughout the several views, and:

FIG. 1 is a circuit diagram of a secondary battery degradation determination device according to a first embodiment of the present invention;

FIG. 2 is a block diagram showing a conceptual configuration of a voltage sensor and a controller in the secondary battery degradation determination device;

FIG. 3 is a flow chart showing an example of operation of the secondary battery degradation determination device;

FIG. 4 is a circuit diagram of a secondary battery degradation determination device according to another embodiment of the present invention;

FIG. 5 is a circuit diagram of a secondary battery degradation determination device according to still another embodiment of the present invention;

FIG. 6 is a circuit diagram of a secondary battery degradation determination device according to still another embodiment of the present invention;

FIG. 7 is a circuit diagram of a secondary battery degradation determination device according to still another embodiment of the present invention; and

FIG. 8 is a circuit diagram of a secondary battery degradation determination device according to still another embodiment of the present invention.

### DESCRIPTION OF EMBODIMENTS

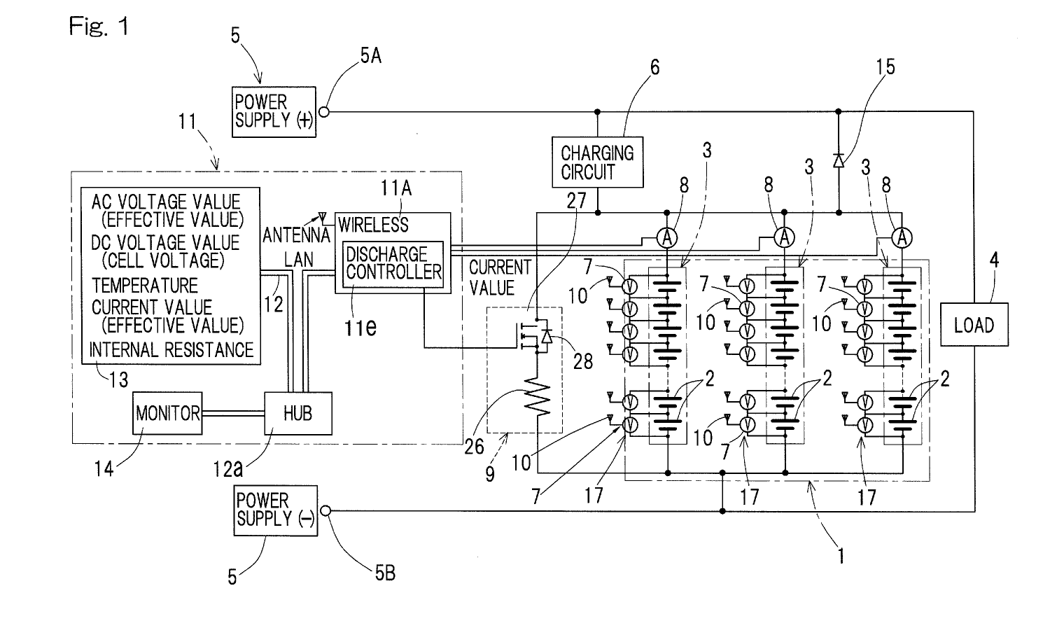

A first embodiment of a secondary battery degradation determination device of the present invention is described with reference to FIG. 1 to FIG. 3. In FIG. 1, a power supply 1 subjected to degradation determination is an emergency power supply in data centers, mobile phone base stations, or other various types of power supply devices for which stable electric power supply is required. The power supply 1 has a plurality of battery groups 3 respectively including a plurality of batteries 2 that are connected in series, each battery 2 being a secondary battery. These battery groups 3 are connected in parallel, and are connected to a load 4. Each battery 2 may be a battery that includes only one cell, or may be a battery in which a plurality of cells are connected in series.

A main power supply 5 has positive and negative terminals 5A and 5B connected to the positive and negative terminals of the load 4. The emergency power supply 1 is connected via a charging circuit 6 and a diode 15 to the positive terminal 5A, and is directly connected to the negative terminal 5B, of the main power supply 5. The diode 15 is connected in parallel to the charging circuit 6 in the direction in which current is caused to flow from the emergency power supply 1 to the load 4. The main power supply 5 is implemented as a DC power supply or the like which is connected to, for example, a commercial AC power supply via a rectification circuit and a smoothing circuit (both not shown), and which converts AC power into DC power.

The positive potential of the emergency power supply 1 is lower than the positive potential of the main power supply 5, and does not normally cause flow to the load 4. However, when the main power supply 5 stops or the function thereof decreases, the potential at the main power supply 5 side decreases, and thus, feeding is performed via the diode 15 to the load 4 by use of electric charge stored in the emergency power supply 1. The charging type in which the charging circuit 6 is connected as described above is called a trickle charging type.

This secondary battery degradation determination device is a device that determines degradation of each battery 2 in the power supply 1. The secondary battery degradation determination device includes a plurality of voltage sensors 7 individually connected to the respective batteries 2 and a plurality of current sensors 8 respectively connected to the battery groups 3. This secondary battery degradation determination device further includes a discharging circuit 9 which applies measurement current containing an AC component, to each battery group 3 and a sensor-specific wireless communicator which is provided to each voltage sensor 7 and which wirelessly transmits a measurement value of voltage of the AC component that has been measured. A controller 11 included in the secondary battery degradation determination device receives the measurement value transmitted by each sensor-specific wireless communicator 10, which calculates an internal resistance of each battery 2 by use of the received measurement value, and which determines degradation of the battery 2 on the basis of the internal resistance.

The discharging circuit 9 is implemented as a series circuit of a current limiting resistor 26 and a switching element 27, and is connected in parallel to each battery group 3. The switching element 27 is a semiconductor element such as a thyristor or a transistor. A diode 28 for providing bypass is connected in parallel to the switching element 27. The switching element 27 is driven to open and close by a discharge controller 11e in a main controller 11A of the controller 11 described later such that current flowing in the discharging circuit 9 becomes current having a pulse shape or a sine wave shape. The discharge controller 11e may be implemented by hardware only, or may be implemented by a microcomputer or a CPU that forms the main controller 11A.

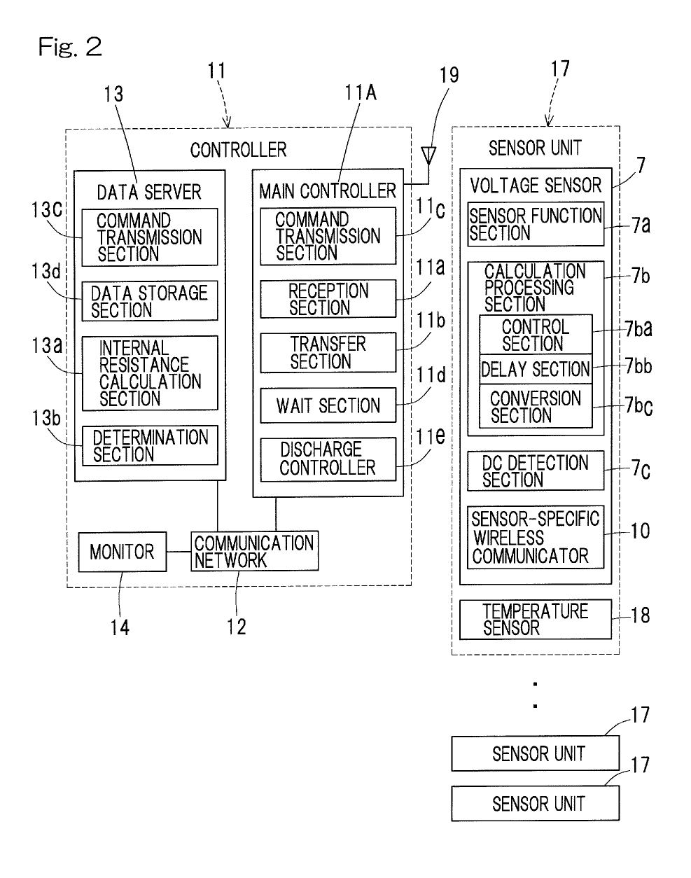

Each voltage sensor 7 detects an AC component and a DC component of voltage, and includes a sensor function section 7a and a calculation processing section 7b as shown in FIG. 2. The sensor function section 7a is implemented as a voltage detection element or the like. The calculation processing section 7b is provided with: a control section 7ba which executes a provided command; a delay section 7bb which delays, by a predetermined time period, the start of measurement by the sensor function section 7a in response to the command; and a conversion section 7bc which converts an analog detection value of AC voltage detected by the sensor function section 7a, into an effective value or an average value in the form of a digital signal. In addition to these, the voltage sensor 7 has a DC detection section 7c which detects DC voltage, and the detection value of the DC component detected by the DC detection section 7c is also transmitted from the sensor-specific wireless communicator 10. It should be noted that the sensor function section 7a may also serve as the DC detection section 7c. The respective voltage sensors 7 have a transmission order set in advance in terms of transmission delay time by the delay section 7bb or another means, and sequentially transmit measurement values after the transmission delay time in the set order such that the measurement values are transmitted in a time multiplexed manner from the respective voltage sensors 7.

In the present embodiment, a temperature sensor 18 which measures the temperature around the battery 2 and the temperature of the battery is provided, and a sensor unit 17 is formed at least by the voltage sensor 7 and the temperature sensor 18. The detected temperature detected by the temperature sensor 18 is transmitted to the controller 11 through the sensor-specific wireless communicator 10, together with a voltage measurement value expressed as the effective value or the average value of the voltage sensor 7.

In the present embodiment, the controller 11 is formed by a main controller 11A having connected thereto a data server 13 and a monitor 14 via a communication network 12. In the present embodiment, the communication network 12 is implemented as a LAN, and has a hub 12a. The communication network 12 may be a wide area network. Through the communication network 12 and other communication networks, the data server 13 can communicate with personal computers (not shown) at remote places, and data can be monitored from any place.

The main controller 11A includes: a reception section 11a which receives a detection value detected by each voltage sensor 7 and transmitted from a corresponding sensor-specific wireless communicator 10; a transfer section 11b which transfers the measurement value received by the reception section 11a, to the communication network 12; a command transmission section 11c which wirelessly transmits a command such as a transmission start to the sensor-specific wireless communicator 10 of each voltage sensor 7; a wait section 11d described later; and the discharge controller 11e. The discharge controller 11e controls the switching element 27 so as to open and close such that discharge current in the form of pulses or having a pseudo sine wave shape is generated in the discharging circuit 9 (FIG. 1). For example, the switching element 27 is turned on and off in a constant cycle. In FIG. 2, wireless transmission and reception by the command transmission section 11c and the reception section 11a are carried out via an antenna 19.

As shown in FIG. 1, each current sensor 8 is connected through wiring to the main controller 11A, and the measurement value of the current is transferred together with a voltage measurement value from the transfer section 11b shown in FIG. 2. The command transmission section 11c of the main controller 11A may generate a command by itself, but in the present embodiment, in response to a measurement start command transmitted from the data server 13, the command transmission section 11c transfers the measurement start command to the sensor-specific wireless communicator 10 of each voltage sensor 7. It should be noted that the main controller 11A or each current sensor 8 is provided with a conversion section (not shown) which converts the measurement value measured by the current sensor 8 into an effective value or an average value.

As described above, the controller 11 has a function of transmitting the command to each sensor-specific wireless communicator 10, and the sensor-specific wireless communicator 10 has a function of providing, upon receiving the command, an instruction that corresponds to the command, to the calculation processing section 7b provided in the voltage sensor 7.

The data server 13 includes an internal resistance calculation section 13a and a determination section 13b. The internal resistance calculation section 13a calculates an internal resistance of the battery 2 in accordance with a predetermined calculation formula, using an AC voltage value (effective value or average value), a DC voltage value (cell voltage), a detected temperature, and a current value (effective value or average value) that have been transmitted from the main controller 11A and received by the internal resistance calculation section 13a. The detected temperature is used in temperature correction.

The determination section 13b determines that degradation has occurred when the calculated internal resistance is not less than a threshold which has been set. A plurality of the thresholds (for two to three stages, for example) are provided, degradation determination is performed in a plurality of stages, and alerts prepared in the plurality of stages are outputted as described later. The determination section 13b has a function of causing the monitor 14 to display a determination result via the communication network 12 or via dedicated wiring. In addition to the above, the data server 13 includes: a command transmission section 13c which transmits a measurement start command to the main controller 11A; and a data storage section 13d for storing data such as the voltage measurement value transmitted from the main controller 11A.

In the configuration described above, the main controller 11A and the discharging circuit 9 may be configured as an integrated controller housed in a single case. In the present embodiment, the controller 11 is configured to include the main controller 11A and the data server 13. However, the main controller 11A and the data server 13 may be configured as one controller 11 housed in a single case, or the main controller 11A and the data server 13 may be implemented, without being separated, as one information processing device formed on one board or the like. In the present embodiment, the current sensor 8 is provided to each battery group 3, but a single current sensor 8 may be provided for the entirety of the degradation determination device, and may be interposed between the charging circuit 6 and the parallel circuit of the battery groups 3, for example. Also in the embodiments below, a single current sensor 8 may be provided.

Operation of the degradation determination device having the configuration described above is described. In this configuration, the AC component is provided to each battery 2 and voltage of the AC component is measured by the corresponding voltage sensor 7. By use of this measurement value, the internal resistance of the battery 2 is calculated and degradation of the battery 2 is determined on the basis of the internal resistance. Thus, degradation can be accurately determined. The internal resistance of the battery 2 has a close relationship with the capacity of the battery 2, that is, the degree of degradation thereof, and thus, if the internal resistance is known, degradation of the battery 2 can be accurately determined. In addition, degradation is determined not for the entirety of the power supply 1 subjected to degradation determination but for each of the individual batteries 2. In this configuration, measurement current containing the AC component is generated, and the internal resistance of the battery 2 is measured to determine degradation, and thus, the measurement can be performed in a relatively simple configuration.

Although a means that generates the AC component for the battery 2 is necessary, measurement current is generated through discharge of the battery. That is, the switching element 27 is driven to open and close by the discharge controller 11e such that current has a pulse shape or a sine wave shape. Thus, no power supply device that produces measurement current from the commercial power supply is necessary, and the means that applies the measurement current can be realized by a simple and compact configuration implemented as the discharging circuit 9 formed by the current limiting resistor 26 and the switching element 27. In this manner, degradation of each battery 2 can be accurately determined, and each of the means that performs from detection of voltage or the like to determination and the means that applies measurement current is simple. Thus, as a whole, a secondary battery degradation determination device that is simple and that can be inexpensively produced is realized.

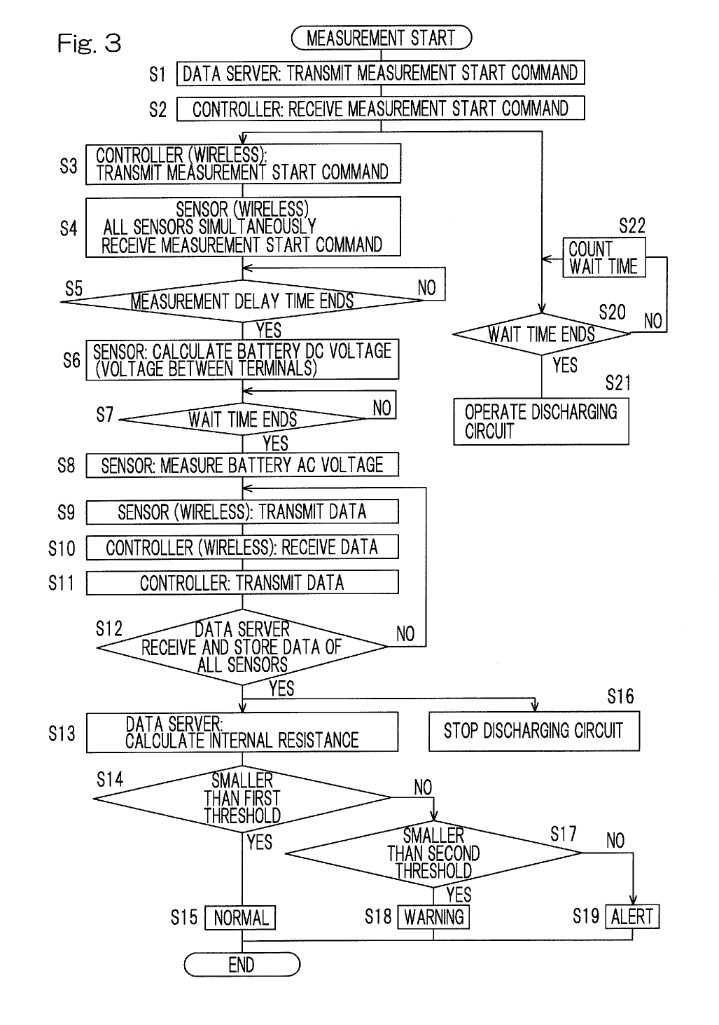

FIG. 3 is a flow chart of one example of specific operation performed by the degradation determination device. The data server 13 transmits a measurement start command from the command transmission section 13c (step S1). The main controller 11A receives the measurement start command from the data server 13 (step S2), and transmits the measurement start command to the sensor-specific wireless communicator 10 of each voltage sensor 7 and each current sensor 8 (step S3). In parallel with the process of this transmission and thereafter, the wait section 11d determines whether a wait time has ended (step S20) and counts the wait time (step S22). When the set wait time has ended, the discharging circuit 9 is caused to operate (step S21).

The measurement start command transmitted in step S3 is received by all the voltage sensors 7 (step S4). Each voltage sensor 7 waits until its own measurement delay time ends (step S5), and measures DC voltage (voltage between terminals) of the battery 2 (step S6). Then, the voltage sensor 7 waits until the wait time ends (step S7), and measures AC voltage of the battery 2 (step S8). As for the measurement of AC voltage, a measurement value that has been directly obtained is converted into an effective voltage or an average voltage, and the converted value is outputted as a measurement value.

The measured DC voltage and AC voltage are wirelessly transmitted by the sensor-specific wireless communicator 10 after the transmission delay time for the voltage sensor 7 has elapsed (step S9), and are wirelessly received by the main controller 11A of the controller 11 (step S10). The main controller 11A transmits the received DC voltage and AC voltage to the data server 13, through the communication network 12 such as a LAN, together with detection values detected by the current sensor 8 and the temperature sensor 18 (FIG. 2) (step S11). The data server 13 receives data sequentially transmitted from sensors such as the voltage sensors 7, and stores the data in the data storage section 13d (step S12). The steps from the wireless transmission in step S9 through the data storage performed by the data server 13 are performed until reception and storage of data from all the voltage sensors 7 end (NO in step S12).

After the reception and storage have ended (YES in step S12), an end signal indicating the end is transmitted from the data server 13 to the main controller 11A and a current application control signal is outputted from the main controller 11A, whereby the discharging circuit 9 is caused to stop (step S16), and in the data server 13, the internal resistance of each battery 2 is calculated by the internal resistance calculation section 13a (step S13).

The determination section 13b of the data server 13 compares the calculated internal resistance with a first threshold predetermined as appropriate (step S14), and when the calculated internal resistance is smaller than the first threshold, the determination section 13b determines that the battery 2 is normal (step S15). When the calculated internal resistance is not smaller than the first threshold, the determination section 13b further compares the calculated internal resistance with a second threshold (step S17). When the calculated internal resistance is smaller than the second threshold, a warning, which is an alert for calling attention is outputted (step S18). When the calculated internal resistance is not smaller than the second threshold, an alert, which is a stronger notification than a warning, is outputted (step S19). The alert and the warning are displayed on the monitor 14 (FIG. 1). When the battery 2 is normal, an indication that the battery 2 is normal may be displayed on the monitor 14, or may not be displayed in particular. The display of the alert and the warning on the monitor 14 may be performed by using a symbol such as a predetermined icon, or may be performed by lighting a predetermined portion, for example. In this manner, degradation determination regarding all the batteries 2 in the emergency power supply 1 is performed. FIG. 3 is an example of a two-stage degradation determination (and a two-stage display of an alert, etc.).

According to this secondary battery degradation determination device, as mentioned above, the voltage sensors 7 are provided for the respective batteries 2, and each receive and transmit data in the form of a digital signal through wireless communication. Therefore, even in a case of the emergency power supply 1 that is provided with several tens to several hundreds of batteries 2, there is no need to take into consideration the electric reference potential (ground level) for each battery 2. Thus, neither differential operation nor an isolation transformer is required. In addition, since the measurement value measured by each of the plurality of the voltage sensors 7 is wirelessly transmitted, no complicated wiring is necessary. Accordingly, a simple and inexpensive configuration can be realized.

The measurement value measured by each voltage sensor 7 is converted into an effective value or an average value indicated as a digital signal, and the digital signal is transmitted. Therefore, compared with a case where a signal having a voltage waveform is sent, the transmission data amount is significantly reduced. Calculation of the internal resistance of the battery 2 can be accurately performed by use of the effective value or the average value. Even in a case where only voltage is measured, the internal resistance of the battery 2 can be calculated with, for example, an assumption that current has a constant value. However, if the current actually flowing in the battery 2 is measured and both the voltage and the current are obtained, the internal resistance can be more accurately calculated. Since the current flowing in the batteries 2 arranged in series is the same, it is sufficient that one current sensor 8 is provided for each battery group 3.

The controller 11 transmits a measurement start command to the sensor-specific wireless communicator 10 of each voltage sensor 7, and this command causes measurement of the voltage sensor 7 to start. Accordingly, measurement start timings of the voltage sensors 7 that exist by a large number can be adjusted. In this case, the controller 11 simultaneously transmits, in serial transmission or parallel transmission, the measurement start command to each voltage sensor 7, and each voltage sensor 7 simultaneously performs measurement after a lapse of a measurement start delay time. After the measurement has ended, the controller 11 sequentially transmits a data transmission request command to each voltage sensor 7, the voltage sensor 7 that has received the command transmits data, and this procedure is repeated, whereby data communication may be performed. In the present invention, after a certain time period from the transmission of the data transmission request command, the controller 11 may send a re-transmission request to a voltage sensor 7 from which data has not been received.

As another example, in a case where measurement is performed after a lapse of only a measurement start delay time that is predetermined for each voltage sensor 7, even when a measurement start command is simultaneously transmitted to each sensor-specific wireless communicator 10, measurements respectively performed by the large number of voltage sensors 7 can be sequentially carried out and transmission can be carried out such that wireless transmission and reception are not hindered. For example, a transmission start command is a global command, and is simultaneously obtained by each voltage sensor 7.

After a certain time period from the transmission of the measurement start command, the controller 11 sends a re-transmission request to a voltage sensor 7 from which data has not been received. There are cases where, due to some temporary transmission failure or the like, the sensor-specific wireless communicator 10 of some of the voltage sensors 7 cannot receive the measurement start command. Even in such a case, if the re-transmission request is sent, voltage can be measured and transmitted, and thus, voltage measurement values of all the batteries 2 in the power supply can be obtained. Whether or not the measurement start command has been successfully received may be determined, on the controller 11 side, on the basis of whether or not a voltage measurement value has been received.

Instead of simultaneously transmitting the measurement start command as described above, the controller 11 may individually transmit a data request command to the sensor-specific wireless communicator 10 of each voltage sensor 7, and may receive data sequentially. In this configuration, the delay section 7bb at the voltage sensor 7 side is not necessary, and the configuration at the voltage sensor 7 side is simplified. Since the controller 11 outputs an alert prepared in a plurality of stages, in accordance with the magnitude of the calculated internal resistance, urgency of the need of battery replacement can be recognized. Thus, without performing unnecessary battery replacement, it is possible to perform maintenance planning and preparation smoothly and quickly.

Specifically, the controller 11 or each component therein is configured by software functions on a processor (not shown) or hardware circuits that can output results by performing calculation using: LUTs (look up table) realized by software or hardware; or predetermined transform functions stored in a software library, hardware equivalent thereto, and the like; and, if necessary, comparison functions, arithmetic operation functions in a library, hardware equivalent thereto, and the like.

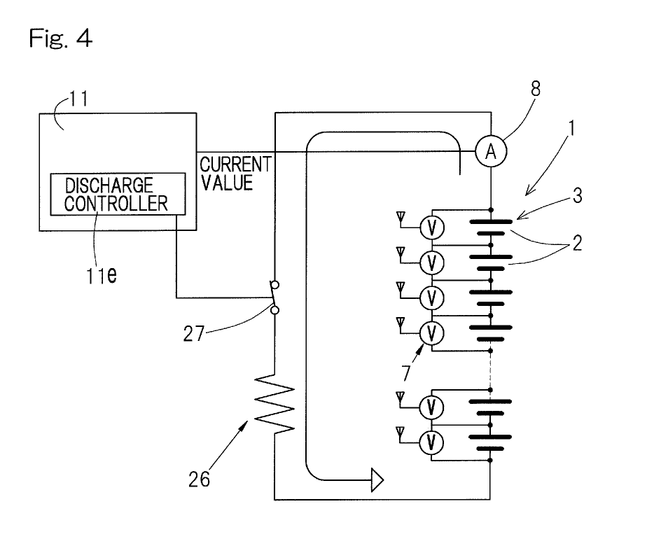

FIG. 4 shows another embodiment of the present invention. In this example, the emergency power supply 1 is implemented as one battery group 3, and is a power supply that can be used for various usages, without being limited to emergency use. The emergency power supply 1 is not connected to the charging circuit. The controller 11 is implemented as a single computer or the like, and includes the command transmission section 11c, the data storage section 13d, the internal resistance calculation section 13a, and the determination section 13b shown in FIG. 2, although not shown, in addition to the discharge controller 11e. As in the embodiment described above, also this configuration has an advantage that the secondary battery degradation determination device can be obtained a simple configuration, can be inexpensively produced, and can accurately determine degradation of each battery 2 in the power supply 1 subjected to determination, wherein, in particular, a generation means for measurement current containing an AC component has a simple and compact configuration. The other configurations and effects are the same as those in the first embodiment described above with reference to FIGS. 1 to 3.

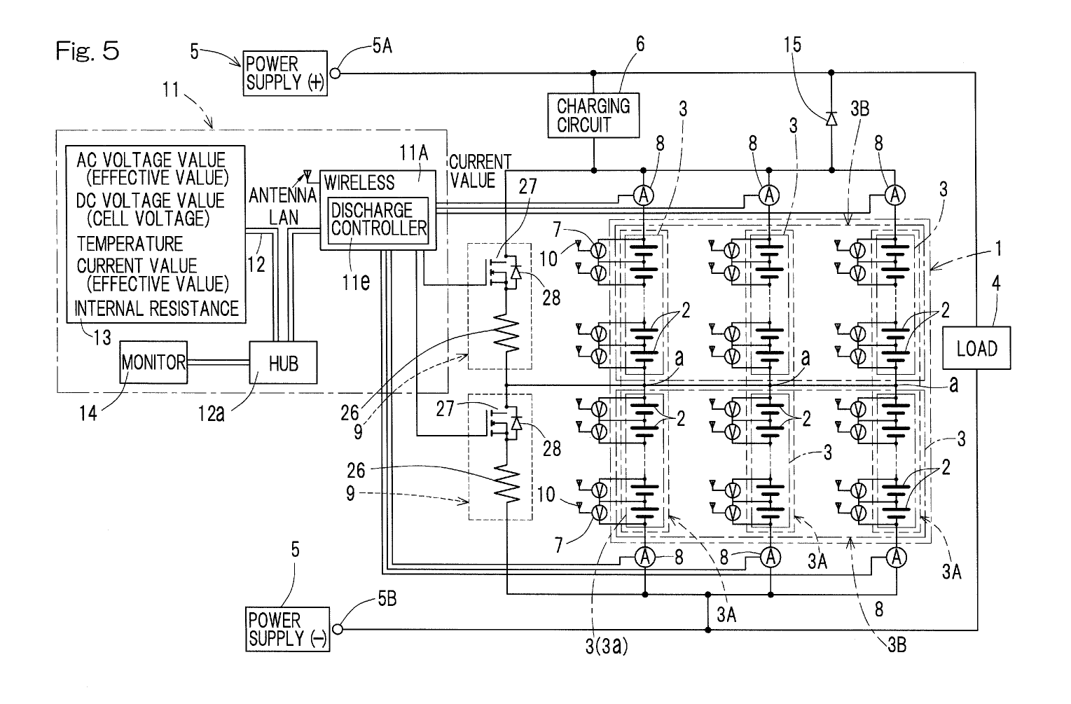

FIG. 5 to FIG. 8 each show still another embodiment. In these embodiments, the configurations other than the matters specifically described below are the same as those in the first embodiment shown in FIG. 1 to FIG. 3, and the effects described in the first embodiment are obtained.

With reference to FIG. 5, in the power supply 1, a plurality of series connection bodies 3A are connected in parallel, and each series connection body 3A includes a plurality (two in FIG. 5) of battery groups 3 that are connected in series. Among the plurality of series connection bodies 3A, portions “a” between individual battery groups 3 that correspond to each other are mutually connected (with one connection line), and among the plurality of series connection bodies 3A, battery groups 3 that are connected in parallel to each other form a parallel connection body 3B. The discharging circuit 9 is provided to each parallel connection body 3B, and two discharging circuits 9 exist in total.

In other words, if the series connection body 3A in the power supply 1 is considered as one battery group 3, this battery group 3 is divided into a plurality of (two) battery group divided bodies 3a that are arranged in the series direction, and the battery group divided bodies 3a are connected in parallel to the battery group divided bodies 3a of another battery group. In this configuration, the discharging circuit 9 is provided in parallel to each parallel connection body 3B of the battery group divided bodies 3a. The number of divisions is not specified, but in each battery group divided body 3a, a plurality of batteries 2 are connected in series.

In a case where the power supply 1 is an emergency power supply or the like in a data center, voltage of the series connection bodies of the batteries 2 in the entirety of the power supply 1 is high voltage that exceeds 300 V, for example. Therefore, if the discharging circuit 9 is provided for the entirety of the power supply 1, the switching element 27, which is a power element for applying measurement current, needs to have high withstand voltage. However, by employing a configuration in which the series connection body of the batteries 2 is divided into two parts in the series direction as in the present embodiment, it is possible to use an element 27 that has low withstand voltage, as the switching element 27 which is the power element for measurement current application in the discharging circuit 9.

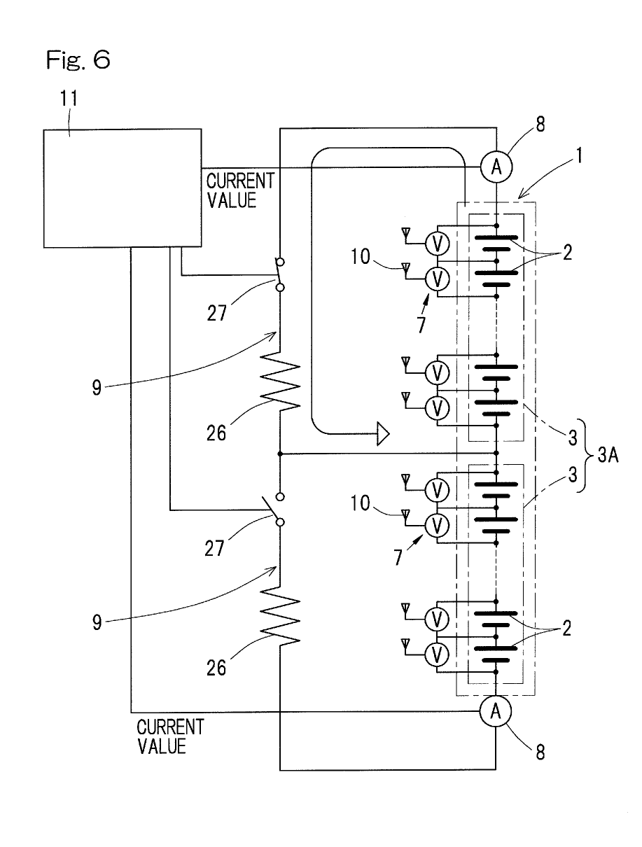

In the embodiment shown in FIG. 6, the power supply 1 is implemented as a series connection body 3A of two battery groups 3, and is a power supply that can be used for various usages, without being limited to emergency use. The power supply 1 is not connected to the charging circuit. The controller 11 is implemented as a single computer or the like, and includes, although not shown in FIG. 6, the discharge controller 11e shown in FIG. 1, and the command transmission section 11c, the data storage section 13d, the internal resistance calculation section 13a, and the determination section 13b shown in FIG. 2.

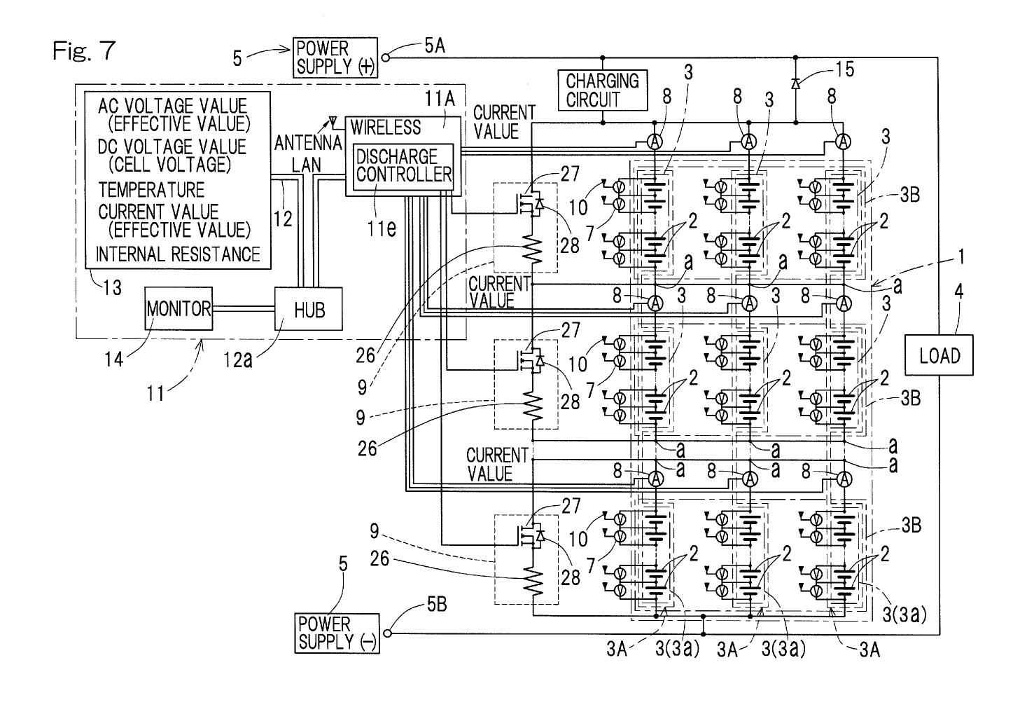

The embodiment shown in FIG. 7 is an example in which, in comparison with the embodiment shown in FIG. 5, each series connection body 3A is formed by three or more battery groups 3 connected in series. In other words, if a series connection body 3A of the batteries 2 in the power supply 1 is considered as one battery group 3, this battery group 3 is formed by three or more battery group divided bodies 3a. Among the plurality of series connection bodies 3A, portions “a” (a plurality of portions “a” exist in a series connection body 3A) between individual battery groups 3 that correspond to each other are mutually connected (with two or more connection lines), and the discharging circuit 9 is provided in parallel to each parallel connection body 3B, and three or more discharging circuits 9 are included in total. Also in the present embodiment, a switching element 27 that has low withstand voltage can be used as the switching element 27 which is the power element for measurement current application.

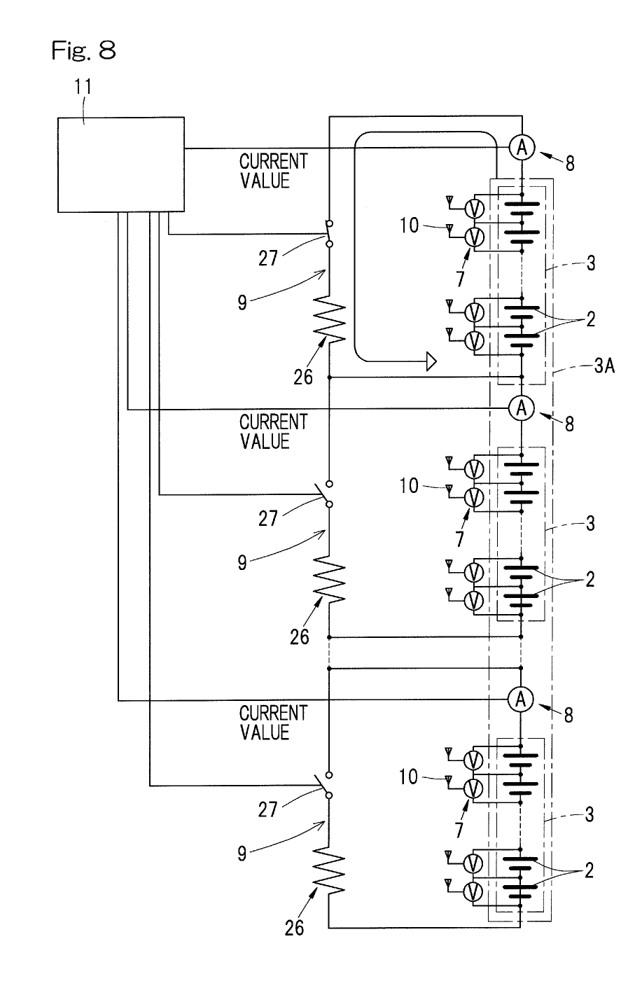

The embodiment shown in FIG. 8 is an example in which, in comparison with the embodiment shown in FIG. 6, the series connection body 3A is formed by three or more battery groups 3 connected in series. In other words, if the series connection body 3A of the batteries 2 in the power supply 1 is considered as one battery group 3, this battery group 3 is formed by three or more battery group divided bodies 3a. The discharging circuit 9 is provided in parallel to each parallel connection body 3B, and three or more discharging circuits 9 are included in total. Also in the present embodiment, a switching element 27 that has low withstand voltage can be used as the switching element 27 which is the power element for measurement current application.

Although the present invention has been fully described in connection with the preferred embodiments thereof with reference to the accompanying drawings which are used only for the purpose of illustration, those skilled in the art will readily conceive numerous changes and modifications within the framework of obviousness upon the reading of the specification herein presented of the present invention. Accordingly, such changes and modifications are, unless they depart from the scope of the present invention as delivered from the claims annexed hereto, to be construed as included therein.

### REFERENCE NUMERALS

1 . . . power supply
2 . . . battery
3 . . . battery group
3A . . . series connection body
3B . . . parallel connection body
4 . . . load
5 . . . main power supply
5A, 5B . . . terminal
6 . . . charging circuit
7a . . . sensor function section
7b . . . calculation processing section
7ba . . . control section
7bb . . . delay section
7bc . . . conversion section
7c . . . DC detection section
8 . . . current sensor
9 . . . discharging circuit
10 . . . sensor-specific wireless communicator
11 . . . controller
11A . . . main controller
11a . . . reception section
11b . . . transfer section
11c . . . command transmission section
11d . . . wait section
1e . . . discharge controller
12 . . . communication network
13 . . . data server
13a . . . internal resistance calculation section
13b . . . determination section
14 . . . monitor
15 . . . diode
17 . . . sensor unit
18 . . . temperature sensor
19 . . . antenna
25 . . . open/close switch
26 . . . current limiting resistor
27 . . . switching element
a . . . portion

What is claimed is:

1. A secondary battery degradation determination device for batteries in a power supply in which a plurality of battery groups are connected in parallel or a single battery group is provided, each battery group being connected to a load and including a plurality of batteries that are connected in series, each battery being a secondary battery, the secondary battery degradation determination device being configured to determine degradation of each of the batteries and comprising:
a plurality of voltage sensors, each individually connected to a corresponding battery, and each configured to measure voltage of an AC component of voltage that has been applied to the battery;
a discharging circuit connected in parallel to the battery group and implemented as a series circuit of a current limiting resistor and a switching element;
a discharge controller configured to drive the switching element so as to open and close such that current flowing in the discharging circuit becomes current having a pulse shape or a sine wave shape;
an internal resistance calculation section configured to calculate an internal resistance of each battery provided with the corresponding voltage sensor, by use of a measurement value measured by the voltage sensor, and
a determination section configured to determine degradation of the battery by use of the internal resistance calculated by the internal resistance calculation section.

2. The secondary battery degradation determination device as claimed in claim 1, wherein
a current sensor is connected to each battery group, and
the internal resistance calculation section calculates the internal resistance by use of a measurement value measured by the current sensor together with the measurement value measured by the voltage sensor.

3. The secondary battery degradation determination device as claimed in claim 1, wherein
each voltage sensor includes a conversion section configured to convert a measured voltage value into an effective value or an average value, and
the internal resistance calculation section calculates the internal resistance by use of the effective value or the average value outputted by the voltage sensor.

4. The secondary battery degradation determination device as claimed in claim 1, comprising
a sensor-specific wireless communicator configured to wirelessly transmit the measurement value of the voltage measured by the corresponding voltage sensor.

5. The secondary battery degradation determination device as claimed in claim 1, wherein
a plurality of the battery groups are connected in series to form a series connection body;
a plurality of the series connection bodies are connected in parallel, and among the plurality of the series connection bodies, portions between individual battery groups that correspond to each other are mutually connected; and
among the plurality of the series connection bodies, battery groups that are connected in parallel to each other form a parallel connection body, and the discharging circuit is provided for each parallel connection body.
